(19) United States
(12) Patent Application Publication
(10) Pub. No.: US 2025/0118555 A1
(43) Pub. Date: Apr. 10, 2025

(54) SELECTIVE PASSIVATION OF PHOTORESISTS

(71) Applicant: Tokyo Electron Limited, Tokyo (JP)

(72) Inventors: Ankur Agarwal, Austin, TX (US); Michael Carcasi, Austin, TX (US)

(21) Appl. No.: 18/484,372

(22) Filed: Oct. 10, 2023

(51) Int. Cl. H01L 21/027; G03F 7/004; H01L 21/308; H01L 21/311; H01L 21/3213

(52) U.S. Cl. CPC H01L 21/0274; H01L 21/308; H01L 21/31144; H01L 21/32139; G03F 7/0044

(57) ABSTRACT

A method of processing a substrate includes forming a photoresist layer over the substrate, exposing the substrate to a pattern of an actinic radiation, where the exposing causes a photo-reaction in an exposed portion of the photoresist layer. The method includes treating the photoresist layer with a binding agent, where the binding agent is selectively adsorbed on a first portion of the photoresist layer, and performing a development process to remove a second portion of the photoresist, the first portion remaining after the development process.

### TECHNICAL FIELD

The present invention relates generally to a method of processing a substrate, and, in particular embodiments, to selective passivation of photoresists.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation, which includes a range of possible wavelengths, to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning at nanoscale features.

### SUMMARY

A method of processing a substrate includes forming a photoresist layer over the substrate, exposing the substrate to a pattern of an actinic radiation, where the exposing causes a photo-reaction in an exposed portion of the photoresist layer. The method includes treating the photoresist layer with a binding agent, where the binding agent is selectively adsorbed on a first portion of the photoresist layer, and performing a development process to remove a second portion of the photoresist, the first portion remaining after the development process.

A method of processing a substrate includes forming a photoresist layer over the substrate, and exposing the substrate to a pattern of an extreme ultraviolet (EUV) radiation, where the exposing causes a photo-reaction in an exposed portion of the photoresist layer. The method includes treating the photoresist layer with a binding agent including a head group and a tail group, where the head group includes thiol, silane, phosphonate, carboxylates, nitriles, amines, amides, nitrates, or their ionic fragments, and the head group selectively binds to a first portion of the photoresist layer by forming a chemical bond. The method includes forming a second layer selectively over the adsorbed binding agent, and performing a development process to remove a second portion of the photoresist, the first portion remaining after the development process.

A method of processing a substrate includes forming a photoresist layer over the substrate, and exposing the substrate to a pattern of an extreme ultraviolet (EUV), where the exposing causes a photo-reaction in an exposed portion of the photoresist layer. The method includes performing a development process to form a patterned photoresist including a top surface and sidewalls, the top surface and the sidewalls having different surface chemical functional groups. The method includes treating the patterned photoresist with a first binding agent, the first binding agent selectively adsorbing on the top surface or the sidewalls. The method includes performing a pattern transfer process to pattern an underlying layer using the treated patterned photoresist as an etch mask.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross sectional view of an example substrate with a negative tone photoresist during a lithographic exposure in accordance with various embodiments;

FIG. 2 illustrates a cross sectional view of another example substrate with a positive tone photoresist during a lithographic exposure in accordance with various embodiments;

FIGS. 3A-3E illustrate cross sectional views of an example substrate at different stages of a method of patterning with selective photoresist passivation in accordance with various embodiments, wherein FIG. 3A illustrates an incoming substrate with a photoresist layer after lithographic exposure, FIG. 3B illustrates the substrate after selective photoresist passivation with a binding agent, FIG. 3C illustrates the substrate after binding agent crosslinking, FIG. 3D illustrates the substrate after a development step, and FIG. 3E illustrates the substrate after a pattern transfer;

FIG. 4 illustrates a cross sectional view of another example substrate with multilayer photoresist passivation in accordance with alternate embodiments;

FIG. 5 illustrates a cross sectional view of yet another example substrate with multilayer photoresist passivation in accordance with alternate embodiments;

FIGS. 6A and 6B illustrate cross sectional views of another example substrate before and after a treatment with a binding agent in accordance with other embodiments;

FIG. 7 illustrates a cross sectional view of yet another example substrate with sidewall photoresist roughness mitigation in accordance with alternate embodiments;

FIG. 8 illustrates a cross sectional view of yet another example substrate with photoresist pattern modification in accordance with alternate embodiments;

FIG. 9 illustrates an example dispensing system for a method of patterning with selective photoresist passivation in accordance with various embodiments; and

FIG. 10A-10C illustrate process flow charts of methods of patterning with a binding agent in accordance with various embodiments, wherein FIG. 10A illustrates one embodiment of selective photoresist passivation, FIG. 10B illustrates another embodiment of multilayer photoresist passivation, and FIG. 10C illustrates yet another embodiment of photoresist pattern modification.

### DETAILED DESCRIPTION OF ILLUSTRATIVE EMBODIMENTS

This application relates to methods of processing a substrate, and, in particular embodiments, to selective passivation of photoresists for pattern improvement in advanced photolithographic techniques. Optimizing processes for lithography of narrow feature sizes, ca. sub-10 nm, with thin photoresist films of ca. sub-20 nm thickness are necessary to enable high- and hyper-NA (numerical aperture) EUV (extreme-ultraviolet, λ=13.5 nm) lithography processes. Thin photoresist films required in these techniques, despite their advantages for shorter etch cycle time and thereby reduced operational cost and time in principle, present unique challenges with pattern transfer, pattern shape uniformity, and pattern thickness uniformity. Pattern uniformity in feature shape and thickness is important for uniform and repeatable etch pattern transfer. Photoresist film molecule of typical size-scale <1 nm is the fundamental unit of the film. Processing chemicals during the lithography interact or react with the resist surface molecules with inherent stochastics and can result in nanoscale roughness from detachment or attachment of fundamental film unit. As the resist films and features becomes thin, the film is composed of fewer molecular layers, which places even tighter restrictions on film thickness uniformity. Pattern transfer from photoresist pattern with substantial molecular non-uniformity can result in problems such as pinching in line-space and missing holes in pillar patterns. Therefore, it is desired to develop a patterning technique that mitigates the issues arising from the thin photoresist films especially in the high-and hyper-NA EUV lithography processes.

Various embodiments of the methods in this disclosure use binding agents (e.g., self-assembled monolayer molecules) that selectively adsorbs onto a selected portion of the photoresist to improve the patterning. The adsorption of binding agent may be spatially and chemically selective on photoresist films, which may provide a top-surface photoresist passivation (monolayer or multilayer), photoresist roughness mitigation (top surface, sidewalls, or both), and feature modification (e.g., aspect ratio of the patterned photoresist). Tailored design of binding agent enable the application of the methods to various types of photoresist, including metal-oxide/organometallic photoresist (MOR) and chemically amplified photoresist (CAR). Further, the disclosure proposes process flow modifications that can advantageously be integrated with existing lithography process flows. Collectively, the proposed methods can improve pattern quality and uniformity.

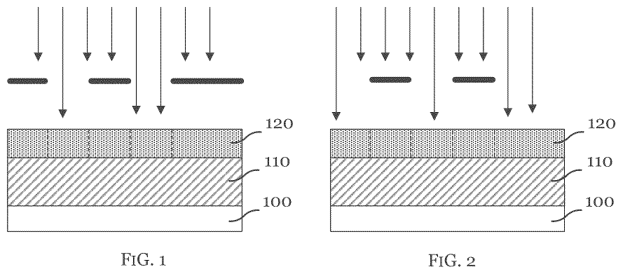

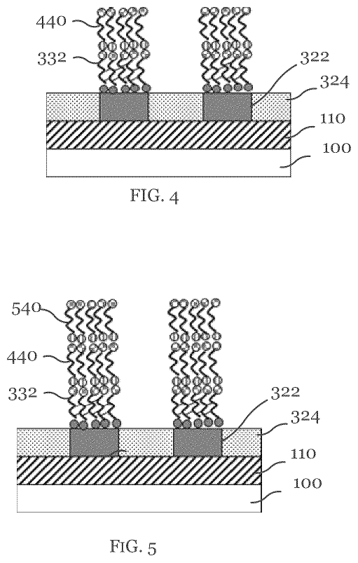

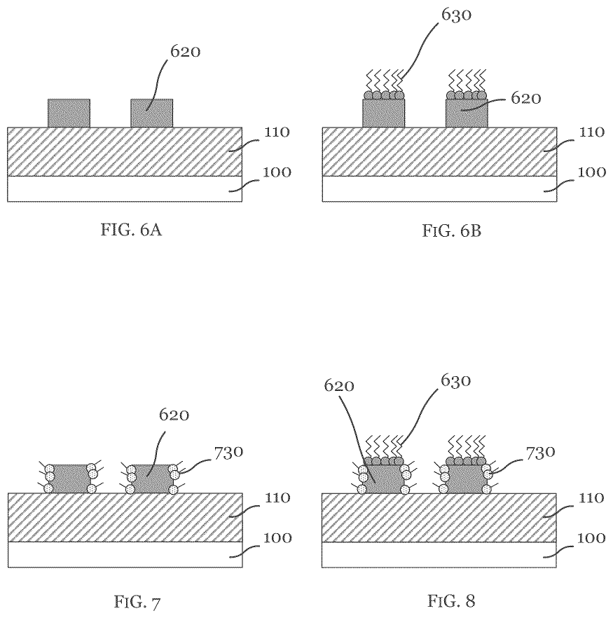

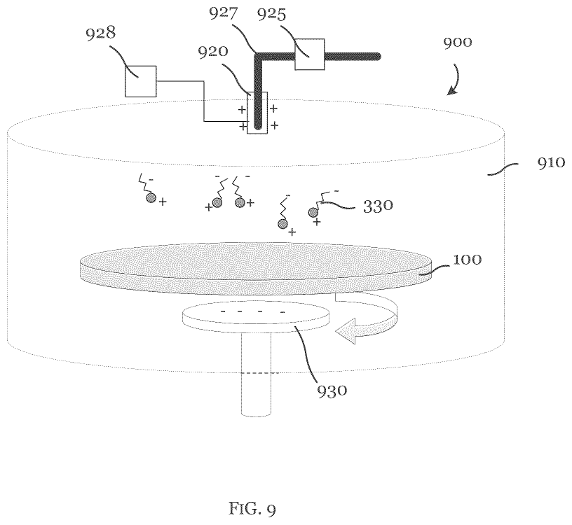

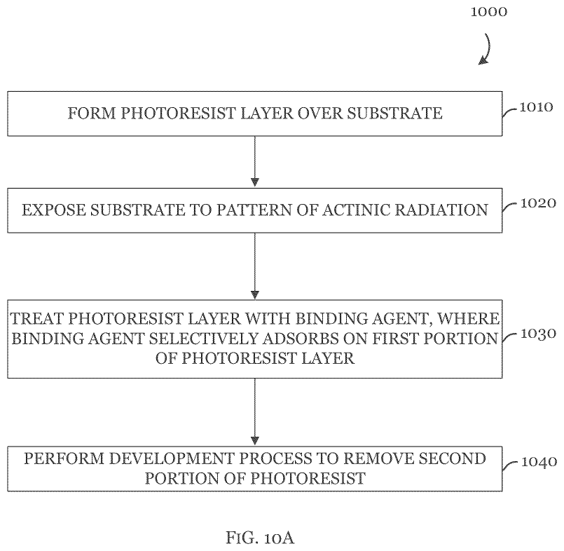

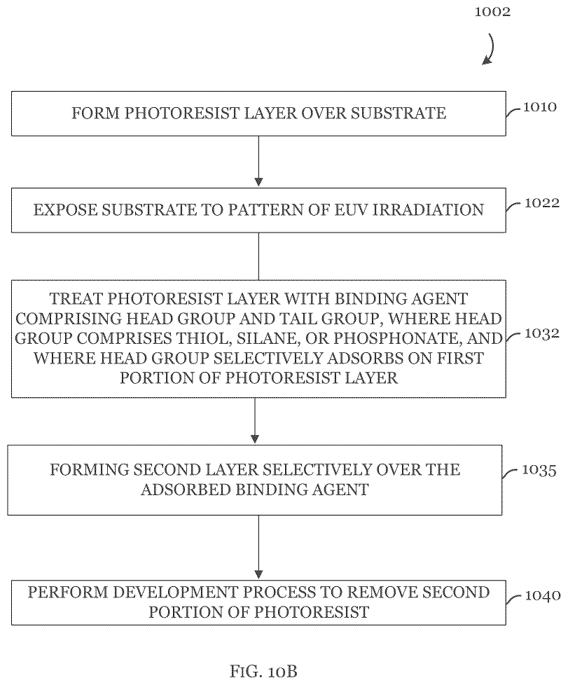

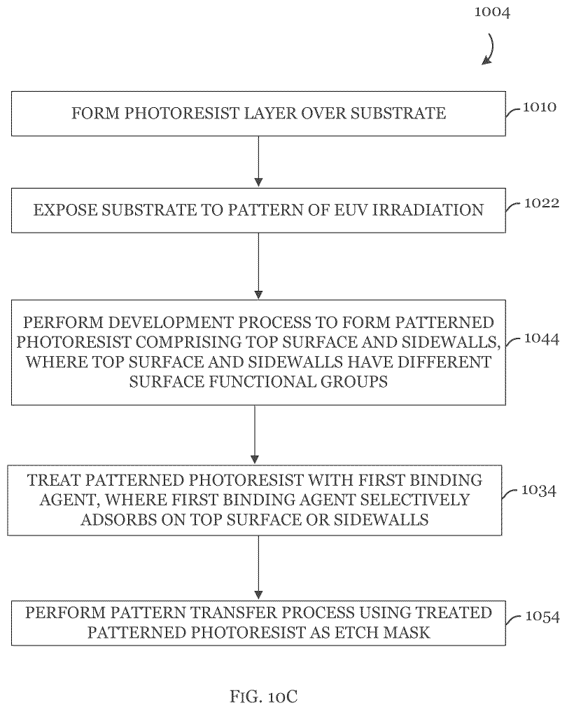

In the following, a process of selective photoresist passivation is first described referring to FIGS. 1-2 and 3A-3E in accordance with various embodiments. Embodiments of multilayer photoresist passivation are then described referring to FIGS. 4-5. Other embodiments of post-develop photoresist pattern modification with binding agent are described referring to FIGS. 6A-6B, and 7-8. An example dispensing system for selective photoresist passivation is illustrated in FIG. 9. Several embodiment process flows of the methods are described referring to FIGS. 10A-10C. All Figures in the disclosure, including the aspect ratios of features, are not to scale and for illustration purposes only. Any list that presents possible compositions, conditions, or process variations includes any reasonable combination thereof, and thus the term “or” used in the list does not indicate any exclusive selection of a particular composition, condition, or process variation.

FIG. 1 illustrates a cross sectional view of an example substrate 100 with a negative tone photoresist during a lithographic exposure in accordance with various embodiments.

FIG. 2 illustrates a cross sectional view of another example substrate with a positive tone photoresist during a lithographic exposure in accordance with various embodiments.

The substrate 100 in FIGS. 1 and 2 may be a part of, or include, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

The semiconductor structure may have undergone a number of steps of processing following, for example, a conventional process. For example, the semiconductor structure may comprise a substrate 100 in which various device regions are formed. At this stage, the substrate 100 may include isolation regions such as shallow trench isolation (STI) regions as well as other regions formed therein.

In FIGS. 1 and 2, the substrate 100 may comprise an intermediate layer 110 formed over the substrate 100. The intermediate layer 110 may be a target for pattern transfer in subsequent processing after the photolithographic process. In various embodiments, the intermediate layer 110 may comprise silicon, silicon oxynitride, organic material, non-organic material, or amorphous carbon. In certain embodiments, the intermediate layer 110 may also be selected to have anti-reflective properties such as by using a silicon bottom anti-reflective coating (Si-BARC). In one or more embodiments, the intermediate layer 110 may be a mask layer comprising a hard mask. The hard mask may comprise silicon nitride, silicon dioxide (SiO₂), or titanium nitride. Further, the intermediate layer 110 may be a stacked hard mask comprising, for example, two or more layers using two different materials. A first layer of the hard mask may comprise a metal-based layer such as titanium nitride, titanium, tantalum nitride, tantalum, tungsten based compounds, ruthenium based compounds, or aluminum based compounds, and a second layer of the hard mask may comprise a dielectric layer such as silicon dioxide, silicon nitride, silicon oxynitride, silicon carbide, amorphous silicon, or polycrystalline silicon. The intermediate layer 110 may be deposited using deposition techniques such as vapor deposition including chemical vapor deposition (CVD), physical vapor deposition (PVD), and atomic layer deposition (ALD), as well as other plasma processes such as plasma enhanced CVD (PECVD), sputtering, and other processes.

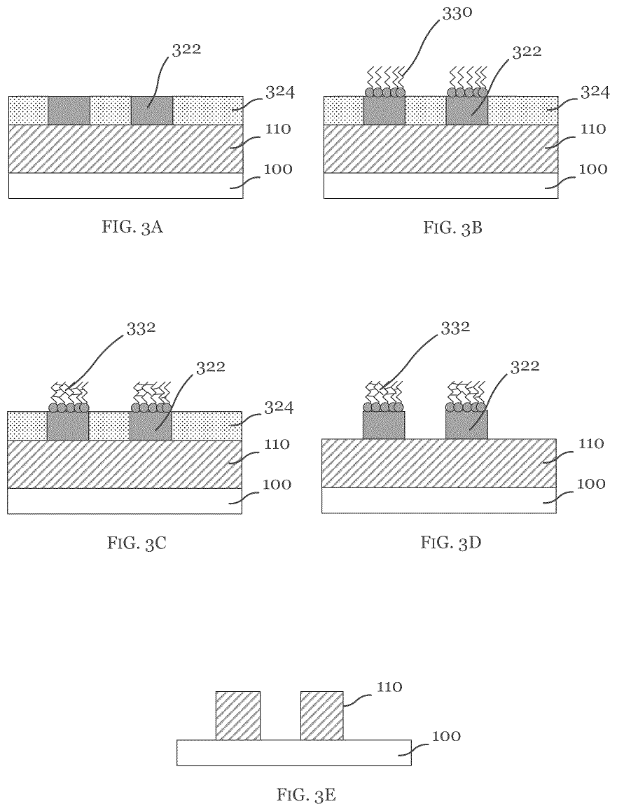

Still referring to FIGS. 1 and 2, a layer of photoresist 120 may be formed over the intermediate layer 110. The photoresist 120 may be a negative tone photoresist (FIG. 1) or a positive tone photoresist (FIG. 2). The negative tone photoresist decreases in solubility for a developing solution upon lithographic exposure and thereby the exposed regions will remain after developing. On the other hand, the positive tone photoresist increases in solubility for a developing solution upon lithographic exposure and the exposed regions will be removed by developing. It should be noted that the methods of selective photoresist passivation in this disclosure may be applied to either type of photoresist (FIG. 1 or 2) as long as the composition of the binding agent may be designed to provide corresponding binding selectivity. For brevity and illustration purpose, the patterns of lithographic exposure in FIGS. 1 and 2 are illustrated as reciprocal so that the subsequent description below (FIGS. 3A-3E, 4-5, 6A-6B, 7-8) can be understood for both negative and positive tone photoresists referring to same Figures.

In various embodiments, the photoresist 120 may comprise a metal-oxide/organometallic photoresist (MOR), which may typically be a negative tone photoresist (FIG. 1), or chemically amplified photoresist (CAR), which may typically be a positive tone photoresist. In various embodiments, the photoresist may be deposited over the intermediate layer 110, e.g., using a coating process or a spin-on process. In other embodiments, particularly for MOR, vapor deposition techniques such as chemical vapor deposition (CVD) may be used.

In FIGS. 1 and 2, the substrate 100 is under a lithographic exposure. In various embodiments, the exposure step may be performed using extreme ultraviolet (EUV, λ=13.5nm) with high numerical aperture (NA; NA=0.55 at high-NA).

The high NA EUV lithography processes can be translated into high-volume manufacturing by meeting targets, including but not limited to, robust process control of thin photoresist films for low depth-of-focus (DOF). DOF is the dimension of image focus and relates to maximum photoresist film thickness that allows for desired sharp aerial image. High- and hyper-NA EUV systems have a DOF ˜⅓ and ˜⅕ of the 0.33 NA system, respectively. Accordingly, in certain embodiments, the photoresist 120 have a thickness of less than 20, for example, 1 nm to 20 nm, designed for high-NA EUV lithographic process. Thin photoresists required to enable reduced DOF and feature-size can suffer from pattern transfer challenges, which may be mitigated by the selective photoresist passivation as described below (e.g., FIGS. 3A-3E).

Further, the critical dimension (CD) of the target pattern for the photoresist 120 may be any size enabled by the photolithographic technique applied. In various embodiments, the CD may be 200 nm or less. In one embodiment, the CD may be less than 20 nm. The pattern defines the first relief pattern that may be transferred to the intermediate layer 110.

In other embodiments, the exposure step may be based on a different photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), deep UV (DUV) lithography, or any suitable photolithography technology. Additionally, the photolithography technology may be mask-based (e.g., projection lithography), maskless (e.g., e-beam lithography), or another suitable type of lithography.

FIGS. 3A-3E illustrate cross sectional views of an example substrate 100 at different stages of a method of patterning with selective photoresist passivation in accordance with various embodiments.

FIG. 3A illustrates a cross sectional view of the substrate 100 with a photoresist layer after lithographic exposure.

In FIG. 3A, the lithographic exposure creates a first portion 322 and a second portion 324 in the layer of the photoresist (e.g., the photoresist 120 in FIG. 1 or 2). In this disclosure, the first portion 322 is the region of the photoresist that will be passivated with binding agent and remain after developing, and the second portion 324 is the region of the photoresist that will be removed by developing. In the case of negative tone photoresist (e.g., FIG. 1), the first portion 322 is the photo-reacted region exposed to the actinic radiation during the lithographic exposure step and the second portion 324 is the un-reacted (un-exposed) region. On the other hand, for positive tone photoresist (e.g., FIG. 2), the first portion 322 is the un-reacted (un-exposed) region and the second portion 324 is the photo-reacted region.

FIG. 3B illustrates a cross sectional view of the substrate 100 after selective photoresist passivation with a binding agent.

In FIG. 3B, the layer of photoresist may be treated with a binding agent 330. The binding agent may selectively adsorb only on the first portion 322 of the photoresist layer. In various embodiments, the binding agent may comprise alkyl carboxylates, alkyl nitriles, alcohols, alkyl aryl ketones, vinyl acetates, alkylsulfates, alkylpyridium, alkyl silanes, alkyl phosphonates, alkyl thiols. In certain embodiments, the binding agent 330 may comprise head-tail amphiphilic fragments with self-assembling characteristics and implicit dipole moment. In other words, a variety of self-assembled monolayer (SAM) molecules may be used. The head group of the binding agent 330 may bind to accessible active sites of the first portion 322 of the photoresist. In certain embodiments, the head group may comprise thiols, silanes, phosphonates, carboxylates, nitriles, amines, amides, nitrates, or their ionic fragments. On the other hand, the tail group limits interaction of one head group to one accessible site by rendering the adjacent sites inaccessible. Examples of the tail group include alkyl, aryl, vinyl, phenyl, peptides, epoxides, esters groups. In one or more embodiments, the tail groups can be terminated by polar aprotic groups.

Further, in various embodiments, the tail group of the binding agent 330 may comprise a crosslinkable functional groups (e.g., biphenyl aromatics, olefins, aliphatics, multivinyls, inorganic acids, alcohols, carboxylates, alkoxides, peptides, amines, sulfhydryls), which may be crosslinked in a subsequent step (e.g., FIG. 3C) to enhance the strength of passivation over the first portion 322.

Specific chemistry to enable selective adsorption to the first portion 322 may depend on the type of the photoresist used. For example, in the case of MOR that is a negative tone photoresist, the first portion 322 may comprise the metal-oxide rich region in the photo-exposed region of the MOR. In the case of CAR that is a positive tone photoresist, the first portion 322 may comprise the carboxylate preserved region in photo-unexposed region of the CAR. Accordingly, the head group of the binding agent 300 may be selected to be able to bind to metal-oxide (for MOR), carboxylate, or blocking site (for CAR). Although not wishing to be limited by any theory, in certain embodiments, the adsorption of the binding agent 330 to these sites may further involve the formation of covalent, ionic, and/or hydrogen bonding. The binding process may be self-limiting when the adsorption at accessible sites approaches saturation coverage. In comparison, the second portion 324 of the photoresist are small organic ligand or polymeric backbone rich, which thereby renders its surface unavailable, unreactive or inaccessible to the binding agent 330.

In various embodiments, wet or dry techniques may be used for selective photoresist passivation. In certain embodiments, the binding agent 330 may be introduced by traditional dispensing and deposition processes, including and not limited to spin-on dispense of binding agent solution to the substrate 100 with an auxiliary nozzle, dip-coating of the substrate 100 in a bath of binding agent solution, spray coating on the substrate 100 with an aerosol, deposition as an aerosol using an atomizer nozzle, deposition using physical vapor deposition (PVD), and chemical vapor deposition (CVD) using suitable binding agent precursors.

FIG. 3C illustrates a cross sectional view of the substrate 100 after crosslinking.

In a subsequent step following the introduction of the binding agent 330, the substrate 100 may be rinsed to remove the unbound/unreacted binding agent. Further, in various embodiments, a bake treatment may subsequently be performed to dry the substrate 100 with a baking apparatus under exhaust or an inert gas flow and a controlled environment. The bake treatment is also to harden the adsorbed binding agent 330 by crosslinking between fragments of the tail groups of the binding agent 330, forming crosslinked binding agent 332. In various embodiments, in a subsequent pattern transfer step (e.g., FIG. 3E), the crosslinked binding agent 332 may advantageously serve as an additional etch mask that passivates the top surface of the patterned photoresist.

At this step, any remaining unbound binding agents may be vaporized with the rinse solvent. In one or more embodiments, the unbound agents may also undergo crosslinking during the bake treatment and removed as aggregated residues by the rinse solvent.

FIG. 3D illustrates a cross sectional view of the substrate 100 after a development step.

In FIG. 3D, the substrate 100 may be treated by a developing solvent by a conventional developing method. In certain embodiments, the developing solvent may comprise an aqueous solution of tetramethylammonium hydroxide (TMAH), but other solvents may be used in other embodiments. After developing, the second portion 324 of the photoresist is selectively removed, leaving the first portion 322 passivated with the crosslinked binding agent 332.

In other embodiments, a dry etch process may be used for development. In particular, the MOR system may be developed by anisotropic etching process, such as reactive ion etch (RIE).

FIG. 3E illustrates a cross sectional view of the substrate 100 after a pattern transfer.

In FIG. 3E, the intermediate layer 210 may be etched by an anisotropic etching process, such as reactive ion etch (RIE) using the passivated photoresist as an etch mask. The anisotropic etching process transfers the pattern defined by the passivated photoresist to the intermediate layer 210. Further in FIG. 3E, any remaining portion of the photoresist may also be removed by the pattern transfer etch or a separate cleaning step.

In the prior embodiments described above (FIGS. 3A-3E), the selective photoresist passivation enabled by binding agent is illustrated as a monolayer coating selectively formed over a portion of the photoresist. The methods of photoresist passivation may also include the formation of a multilayer structure for additional structural reinforcement for the photoresist.

FIG. 4 illustrates a cross sectional view of another example substrate with multilayer photoresist passivation in accordance with alternate embodiments.

FIG. 5 illustrates a cross sectional view of yet another example substrate with multilayer photoresist passivation in accordance with alternate embodiments.

In FIG. 4, the substrate 100 has the same structure as prior embodiments as illustrated FIG. 3C, where the crosslinked binding agent 332 is selectively formed over a portion (the first portion 322) of the photoresist. Over the crosslinked binding agent 332, a second layer 440 may be formed to extend the height of the relief pattern defined by the photoresist. In various embodiments, the height can be extended by one or more sequential- or mixture-coating of ionic, polyion, or hydrophilic layers. In certain embodiments, aprotic groups of the tail group of the first layer of binding agent may be used as a template to form a subsequent layer. The coating can be performed by methods described in the previous embodiment. As illustrated in FIG. 5, the process of layer formation may be repeated for any number of times to enable multilayer growth (e.g., a third layer 540 selectively formed over the second layer 440 in FIG. 5). In one or more embodiments, two types of molecular precursors may be sequentially and cyclically used to form a stack of alternating layers. Accordingly, the extent of multilayer formation may be controlled by the concentration of bilayer chemicals and number of coating cycles.

In alternate embodiments, in addition to top-surface photoresist passivation, the binding agent treatment may also be applied after developing (post-develop treatment) to improve other patterning metrics such as photoresist roughness. In general, the size of patterns developed from thin photoresist films with EUV lithography can be so small that its feature size may be within an order of magnitude of the size a molecule or a cluster of atoms of the photoresist films. At this scale, the inhomogeneity of the photoresist films and photo-chemical stochastics may be manifested as topographical roughness in the feature. The binding agent treatment may advantageously mitigate undesired characteristics arising from top-surface and sidewall roughness as well as sidewall angle or taper of the patterned feature.

FIGS. 6A and 6B illustrate cross sectional views of another example substrate 100 before and after a treatment with a binding agent 630 in accordance with other embodiments. In FIGS. 6A and 6B, the substrate 100 may comprise an intermediate layer 110 and a patterned photoresist 620, and the details of these layers and substrate structure may be identical or similar to those described referring to FIGS. 1, 2, and 3A, and will not be repeated.

In FIG. 6A, a layer of photoresist is patterned and developed, and accordingly the patterned photoresist 620 comprises a top surface and sidewalls. The top surface and sidewalls may have different surface compositions and functional groups, which may enable selective adsorption of the binding agent. For example, the top surface of a chemically amplified photoresist (CAR) after developing may comprise carboxylate—or pendant—(e.g., polar adamantyl, adamantanol, or adamantane) groups, while its sidewall surface may comprise carboxylate—or deblocked—(such as alcohols, carboxylates) groups. In metal-oxide/organometallic resist (MOR), the developed top surface may primarily comprise metal-oxides having transition metal sites with multivalent oxidation states that can exhibit both oxidizing and reducing agent functions. In contrast, the developed MOR sidewall surface may comprise metal hydroxides with bridging oxygens, where the hydroxides can function as potential Brønsted acid sites.

In addition to distinct chemical characteristics between the top surface and sidewalls, the binding agent treatment may also be selective to the bottom surface in the formed trenches after developing. The bottom surface may comprise the exposed underlayer surface, for example, the intermediate layer 110 in FIG. 6A. In various embodiments, typical underlayers for EUV lithography may comprise organosilanes, organosiloxanes, doped-SiO₂, or organo-polymeric compounds, which are chemically distinct from the surfaces derived from MOR or CAR.

In FIG. 6B, in accordance with one embodiment, the post-develop binding agent treatment may target the top surface of the patterned photoresist 620. In one embodiment, the binding agent 630 illustrated in FIG. 6B may target the metal-oxide of MOR top surface or adamantly sites of CAR top surface. In various embodiments, wet or dry techniques may be used for the treatment as previously described referring to FIG. 3B. Exemplary adsorbent chemicals for the binding agent 630 may comprise R—NOₓ, R—COₓ, acrylates, alkyl aryl ketone, pyridines, alkynes, alkenes, ethers, metal amide salts, or macrocyclic hosts such as cucurbituril.

In various embodiments, the post-develop binding agent treatment may provide selective photoresist passivation during pattern transfer or secondary development steps similar to prior embodiments. The treatment may also improve etch resistance of shallow regions of patterned features, and also potentially prevent metal or metal-oxide migration during pattern transfer or secondary development steps. Further, the treatment may also offer the top-surface pattern roughness mitigation. Although not wishing to be limited by any theory, since the topographically rough regions of the patterned photoresist 620 after developing may provide larger contact area for the binding agent 630 than the smooth regions, the binding agent 630 can preferentially bind to the rough regions of the top surface and smoothening the surface.

Further, in certain embodiments, the binding agent 630 may comprise crosslinking fragments such as biphenyl fragments that can be activated by thermal baking. Accordingly, in one or more embodiments, the post-develop binding agent treatment may be followed by a bake treatment for crosslinking the adsorbed binding agent and reinforcing the surface structure prior to a subsequent step (e.g., a pattern transfer) similar to prior embodiments (e.g., FIG. 3C).

FIG. 7 illustrates a cross sectional view of yet another example substrate 100 with sidewall photoresist roughness mitigation in accordance with alternate embodiments.

In alternate embodiments, instead of the top surface of the patterned photoresist 620, the post-develop binding agent treatment may target the sidewalls of the patterned photoresist 620 illustrated in FIG. 6A. In one embodiment, a binding agent 730 illustrated in FIG. 7 may target the metal-hydroxide of MOR sidewalls or carboxylate sites of CAR sidewalls. Exemplary adsorbent chemicals for the binding agent 730 may comprise carbenes, isocyanates, formic acid, ammonium salts, aryl phosphonates, silanes, catechols, or alkanoic acids.

In various embodiments, the treatment may improve various patterning metrics: edge roughness reduction by selective adsorption, increase in feature thickness, improvement of etch resistance of patterned features smaller than target dimension, and sidewall passivation during pattern transfer or secondary development steps.

FIG. 8 illustrates a cross sectional view of yet another example substrate 100 with photoresist pattern modification in accordance with alternate embodiments.

In yet other embodiments, a mixture of two or more binding agents with different binding characteristics may be used for the post-develop binding agent treatment. These embodiments enable coating both the top surface and sidewalls with controlled relative concentration, which provides a general methodology for modification of feature size and aspect ratio. Aspect ratio modification may be performed by anisotropic coat of binding agent on the lateral dimension of the patterned photoresist 620 relative to its height. Lithography for narrow width (ca. sub-10 nm) trenches in patterns are susceptible to bridging and scums after pattern development. Using mixture of adsorbent chemicals, albeit increasing the processing steps, can print narrow trenches from developed patterns with wider trenches in thin photoresist films. In one embodiment, as illustrated in FIG. 8, the combination of the binding agent 630 (top-surface selective) and the binding agent 730 (sidewall selective) may be used to enable the photoresist pattern modification.

Although not specifically illustrated in FIGS. 6B and 7-8, in various embodiments, a bilayer or multilayer structure may be formed after the monolayer photoresist passivation by repeating binding cycles using one or more binding agents as described referring to FIGS. 4-5. Further, any layer may further include crosslinking features and the methods may accordingly include any number of additional crosslinking step such as bake treatment at any stage of the process flows.

FIG. 9 illustrates an example dispensing system 900 for a method of patterning with selective photoresist passivation in accordance with various embodiments.

In FIG. 9, the dispensing system 900 comprises a processing chamber 910 configured to dispense a solution or vapor comprising the binding agent 330 through a nozzle 920 toward a substrate 100 held onto a chuck 930. The chuck may be configured to rotate at a controlled spin rate. The dispensing system 900 may further comprise a process gas delivery system and a temperature controller for the chuck 930. The dispensing rate may be controlled by a flow rate controller 925 connected to a supply line 927.

In certain embodiments, the nozzle 920 may further include an electrode connected to a power delivery system 928, which may include a power source and a controller. This feature enables applying a voltage to the electrode at the nozzle 920 and providing electrical charge to the binding agent 330. In other embodiments, the chuck 930 may be configured similarly to be biased relative to the ground or the nozzle 920. In various embodiments, the binding agent 330 may comprise ionic fragments or have internal dipole moment, and the adsorption of the binding agent 330 may be promoted under an applied voltage within the processing chamber 910 by improving binding kinetics and improving configurational order of the binding agent 330 on surface. In one or more embodiments, the voltage may be applied between the nozzle 920 and the chuck 930. For example, the electrode at the nozzle 920 may be used to charge the liquid solution containing the binding agent 330 while the opposite charge electrode at the chuck 930 direct electric field for directed adsorption at the top surface.

FIG. 10A-10C illustrate process flow charts of methods of patterning with a binding agent in accordance with various embodiments. Example process flows follow in accordance with the embodiments already described above referring to FIGS. 1-2, 3B-3E, 4, 6A-6B, and 7-8, and therefore the details will not be repeated.

In FIG. 10A, an example process flow 1000 for selective photoresist passivation starts with forming a photoresist layer over a substrate (block 1010) and exposing the substrate to a pattern of an actinic radiation to causing a photo-reaction in an exposed portion of the photoresist layer (block 1020, FIG. 1 or 2). Subsequently, the photoresist layer may be treated with a binding agent (block 1030, FIG. 3B), where the binding agent selectively adsorbs on a first portion of the photoresist layer, followed by performing a development process to remove a second portion of the photoresist, where the first portion remains after the development process (block 1040, FIG. 3D).

In FIG. 10B, another example process flow 1002 for multilayer photoresist passivation starts with forming a photoresist layer over a substrate (block 1010) and exposing the substrate to a pattern of an extreme ultraviolet (EUV) radiation to cause a photo-reaction in an exposed portion of the photoresist layer (block 1022, FIG. 1 or 2). Subsequently, the photoresist layer may be treated with a binding agent (block 1032, FIG. 3B), where the binding agent comprises a head group and a tail group, where the head group comprises thiol, silane, phosphonate, carboxylates, nitriles, amines, amides, nitrates, or their ionic fragments, and where the head group selectively binds to a first portion of the photoresist layer by forming a chemical bond. A second layer may then be formed selectively over the adsorbed binding agent (block 1035, FIG. 4). After forming the multilayer structure, a development process may be performed to remove a second portion of the photoresist, where the first portion remains after the development process (block 1040).

In FIG. 10C, yet another example process flow 1004 for photoresist pattern modification starts with forming a photoresist layer over a substrate (block 1010) and exposing the substrate to a pattern of an extreme ultraviolet (EUV) radiation to cause a photo-reaction in an exposed portion of the photoresist layer (block 1022, FIG. 1 or 2). Subsequently, a development process may be performed to form a patterned photoresist comprising a top surface and sidewalls (block 1044, FIG. 6A), where the top surface and the sidewalls have different surface chemical functional groups. The patterned photoresist may then be treated with a first binding agent (block 1034, FIG. 6B, 7, or 8), where the first binding agent selectively adsorbs on the top surface or the sidewalls, followed by performing a pattern transfer process to pattern an underlying layer using the treated patterned photoresist as an etch mask (block 1044).

Example embodiments of the invention are described below. Other embodiments can also be understood from the entirety of the specification as well as the claims filed herein.

Example 1. A method of processing a substrate includes forming a photoresist layer over the substrate, exposing the substrate to a pattern of an actinic radiation, where the exposing causes a photo-reaction in an exposed portion of the photoresist layer. The method includes treating the photoresist layer with a binding agent, where the binding agent is selectively adsorbed on a first portion of the photoresist layer, and performing a development process to remove a second portion of the photoresist, the first portion remaining after the development process.

Example 2. The method of example 1, where the exposed portion of the photoresist layer is the first portion, and where an un-exposed portion of the photoresist is the second portion.

Example 3. The method of one of examples 1 or 2, where the photoresist includes an organometallic photoresist.

Example 4. The method of one of examples 1 to 3, where an un-exposed portion of the photoresist layer is the first portion, and where the exposed portion of the photoresist is the second portion.

Example 5. The method of one of examples 1 to 4, where the photoresist includes a chemically amplified photoresist.

Example 6. The method of one of examples 1 to 5, where the forming of the photoresist layer is performed by a spin-on process, the method further including a soft bake after the forming to remove a solvent used for the spin-on process from the substrate.

Example 7. The method of one of examples 1 to 6, further includes, after the exposing, a post-exposure bake.

Example 8. The method of one of examples 1 to 7, further includes, after the treating with the binding agent, inducing a crosslinking reaction in the adsorbed binding agent.

Example 9. The method of one of examples 1 to 8, further includes, after the development process, performing a pattern transfer process to transfer a pattern of the first portion of the photoresist layer to an underlying layer.

Example 10. The method of one of examples 1 to 9, where the treating with the binding agent is performed in a processing chamber, the method further includes applying an electric field within the processing chamber during the treating.

Example 11. The method of one of examples 1 to 10, where the actinic radiation includes extreme ultraviolet (EUV).

Example 12. The method of one of examples 1 to 11, where the binding agent includes a self-assembled monolayer (SAM) molecule.

Example 13. A method of processing a substrate includes forming a photoresist layer over the substrate, and exposing the substrate to a pattern of an extreme ultraviolet (EUV) radiation, where the exposing causes a photo-reaction in an exposed portion of the photoresist layer. The method includes treating the photoresist layer with a binding agent including a head group and a tail group, where the head group includes thiol, silane, phosphonate, carboxylates, nitriles, amines, amides, nitrates, or their ionic fragments, and the head group selectively binds to a first portion of the photoresist layer by forming a chemical bond. The method includes forming a second layer selectively over the adsorbed binding agent, and performing a development process to remove a second portion of the photoresist, the first portion remaining after the development process.

Example 14. The method of example 13, further includes extending a height of a pattern defined by the first portion by forming a multilayer structure including a third layer formed over the second layer.

Example 15. The method of one of examples 13 or 14, where the extending includes a cyclic layer growth process.

Example 16. A method of processing a substrate includes forming a photoresist layer over the substrate, and exposing the substrate to a pattern of an extreme ultraviolet (EUV), where the exposing causes a photo-reaction in an exposed portion of the photoresist layer. The method includes performing a development process to form a patterned photoresist including a top surface and sidewalls, the top surface and the sidewalls having different surface chemical functional groups. The method includes treating the patterned photoresist with a first binding agent, the first binding agent selectively adsorbing on the top surface or the sidewalls. The method includes performing a pattern transfer process to pattern an underlying layer using the treated patterned photoresist as an etch mask.

Example 17. The method of example 16, where the first binding agent selectively adsorbing on the top surface, and the method further including treating the patterned photoresist with a second binding agent, the second binding agent selectively adsorbing on the sidewalls.

Example 18. The method of one of examples 16 or 17, where the first binding agent selectively adsorbing on the sidewalls, and where the adsorption of the first binding agent reduces a surface roughness of the sidewalls.

Example 19. The method of one of examples 16 to 18, where the first binding agent includes a crosslinker, the method further includes, after inducing a crosslinking reaction in the adsorbed first binding agent.

Example 20. The method of one of examples 16 to 19, further includes extending a height of the patterned photoresist by selectively forming a multilayer structure over the first binding agent.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
forming a photoresist layer over the substrate;
exposing the substrate to a pattern of an actinic radiation, the exposing causing a photo-reaction in an exposed portion of the photoresist layer;
treating the photoresist layer with a binding agent, the binding agent being selectively adsorbed on a first portion of the photoresist layer; and
performing a development process to remove a second portion of the photoresist, the first portion remaining after the development process.

2. The method of claim 1, wherein the exposed portion of the photoresist layer is the first portion, and wherein an un-exposed portion of the photoresist is the second portion.

3. The method of claim 2, wherein the photoresist comprises an organometallic photoresist.

4. The method of claim 1, wherein an un-exposed portion of the photoresist layer is the first portion, and wherein the exposed portion of the photoresist is the second portion.

5. The method of claim 4, wherein the photoresist comprises a chemically amplified photoresist.

6. The method of claim 1, wherein the forming of the photoresist layer is performed by a spin-on process, the method further comprising a soft bake after the forming to remove a solvent used for the spin-on process from the substrate.

7. The method of claim 1, further comprising, after the exposing, a post-exposure bake.

8. The method of claim 1, further comprising, after the treating with the binding agent, inducing a crosslinking reaction in the adsorbed binding agent.

9. The method of claim 1, further comprising, after the development process, performing a pattern transfer process to transfer a pattern of the first portion of the photoresist layer to an underlying layer.

10. The method of claim 1, wherein the treating with the binding agent is performed in a processing chamber, the method further comprising applying an electric field within the processing chamber during the treating.

11. The method of claim 1, wherein the actinic radiation comprises extreme ultraviolet (EUV).

12. The method of claim 1, wherein the binding agent comprises a self-assembled monolayer (SAM) molecule.

13. A method of processing a substrate, the method comprising:
forming a photoresist layer over the substrate;
exposing the substrate to a pattern of an extreme ultraviolet (EUV) radiation, the exposing causing a photo-reaction in an exposed portion of the photoresist layer;
treating the photoresist layer with a binding agent comprising a head group and a tail group, the head group comprising thiol, silane, phosphonate, carboxylates, nitriles, amines, amides, nitrates, or their ionic fragments, the head group selectively binding to a first portion of the photoresist layer by forming a chemical bond;
forming a second layer selectively over the adsorbed binding agent; and
performing a development process to remove a second portion of the photoresist, the first portion remaining after the development process.

14. The method of claim 13, further comprising extending a height of a pattern defined by the first portion by forming a multilayer structure comprising a third layer formed over the second layer.

15. The method of claim 14, wherein the extending comprises a cyclic layer growth process.

16. A method of processing a substrate, the method comprising:
forming a photoresist layer over the substrate;
exposing the substrate to a pattern of an extreme ultraviolet (EUV), the exposing causing a photo-reaction in an exposed portion of the photoresist layer;
performing a development process to form a patterned photoresist comprising a top surface and sidewalls, the top surface and the sidewalls having different surface chemical functional groups;
treating the patterned photoresist with a first binding agent, the first binding agent selectively adsorbing on the top surface or the sidewalls; and
performing a pattern transfer process to pattern an underlying layer using the treated patterned photoresist as an etch mask.

17. The method of claim 16, wherein the first binding agent selectively adsorbing on the top surface, and the method further comprising treating the patterned photoresist with a second binding agent, the second binding agent selectively adsorbing on the sidewalls.

18. The method of claim 16, wherein the first binding agent selectively adsorbing on the sidewalls, and wherein the adsorption of the first binding agent reduces a surface roughness of the sidewalls.

19. The method of claim 16, wherein the first binding agent comprises a crosslinker, the method further comprising, after inducing a crosslinking reaction in the adsorbed first binding agent.

20. The method of claim 16, further comprising extending a height of the patterned photoresist by selectively forming a multilayer structure over the first binding agent.
